(19) United States
(12) Patent Application Publication
(10) Pub. No.: US 2020/0203928 A1
(43) Pub. Date: Jun. 25, 2020

(54) HIGH-EFFICIENCY OXIDIZED VCSEL INCLUDING CURRENT DIFFUSION LAYER HAVING HIGH-DOPING EMISSION REGION, AND MANUFACTURING METHOD THEREOF

(71) Applicant: AUK CORP., Jeollabuk-do (KR)

(72) Inventor: Hyung Joo LEE, Gwangju (KR)

(73) Assignee: AUK CORP., Jeollabuk-do (KR)

(21) Appl. No.: 16/518,878

(22) Filed: Jul. 22, 2019

(30) Foreign Application Priority Data
Dec. 24, 2018 (KR) 10-2018-0168138

(51) Int. Cl. H01S 5/183; H01S 5/042; H01S 5/20; H01S 5/02; H01S 5/343

(52) U.S. Cl. CPC H01S 5/18327; H01S 5/0421; H01S 5/2059; H01S 5/18347; H01S 2304/04; H01S 5/0206; H01S 5/3432; H01S 5/34353; H01S 5/18361

(57) ABSTRACT

The present invention relates to a vertical cavity surface emitting laser (VCSEL) and a manufacturing method thereof, and more specifically, to a high-efficiency oxidized vertical cavity surface emitting laser for emitting laser light having a peak wavelength of 860 nm, and a manufacturing method thereof. The vertical cavity surface emitting laser according to the present invention includes a current diffusion layer having a high doping region at least in a portion between an upper electrode and a lower distributed Bragg reflector.

### CLAIM OF PRIORITY

This application claims the benefit of prior Korean Application No. KR 10-2018-0168138 filed on Dec. 24, 2018, which is incorporated by reference in its entirety.

### BACKGROUND OF THE INVENTION

### Field of the Invention

The present invention relates to a vertical cavity surface emitting laser (VCSEL) and a manufacturing method thereof, and more specifically, to a high efficiency oxidized. vertical cavity surface emitting laser for emitting laser light having a peak wavelength of 860 nm, and a manufacturing method thereof.

### Background of the Related Art

Although the efficiency of a general vertical cavity surface emitting laser (VCSEL) is low compared with that of an existing edge emitting laser, laser light is emitted in the vertical direction and the VCSEL may be used in an existing light emitting diode area, and thus it has high marketability.

The VCSEL 10 like this has a structure of a column shape, which stacks a lower electrode 1, a substrate 2, a lower distributed Bragg reflector 3, an active layer 4, a current window 5 for emitting resonance laser light, an oxide layer formed to surround the periphery of the current window, an upper distributed Bragg reflector 7 formed on the top surface of the current window 5 and the oxide layer 6, and an upper electrode 8, as shown in FIG. 1. A trench 9 is formed around the light emitting column, and laser light is emitted toward the top.

Generally, the trench 9 is a trench of a circular shape and is formed using a dry etching technique. The oxide layer 6 is formed as the periphery of the current window 5 is oxidized by an oxidant injected through the trench 9 and adjusts the diameter of the current window 5 which remains without being oxidized through adjustment of oxidizing time. In addition, the upper and lower DBRs are applied on the top and the bottom of the active layer through an epitaxial process. In the case of a VCSEL which emits light of 800 to 1,000 nm, a DBR of a stack structure in which AlₓGa₁₋ₓAs/Al_{y}Ga_{1-y}As (0.8<x<1, 0<y<0.2) is configured is generally used.

Accordingly, the current window (oxide aperture) and the upper and lower DBRs are essential for the characteristic of resonance laser in the manufacturing process. The problem is that as the materials used in these components are materials of the same type, the probability of generating a defect is high since the uppermost part of the upper p-DBR is oxidized together with the current window in the oxidization process. The oxidization process is a process of converting Al of an Al_{0.98}Ga_{0.02}As layer used as the current window into an AlxOy layer by injecting H₂O steam so that the Al may respond to high-temperature steam, and since the upper and lower DBRs configured of AlₓGa₁₋ₓAs/Al_{y}Ga_{1-y}As contain Al, the DBRs are damaged as the DBRs are also oxidized to some extent.

FIG. 2(a) is a view showing an SEM image of a DBR damaged when oxidization is progressed, and when p-metal is applied to the damaged DBR, electrode peeling, current non-uniform injection (decrease in efficiency) or the like will occur later. FIG. 2(b) is a view showing a shape of the current window, in which the black band shape is a trench (dented) area, and the center area is a column area for emitting light, of which the brighter area is the oxidized area. The dark circular area at the center is a light emitting region for directly emitting light, which is expressed as an aperture diameter in the VCSEL.

When high current is applied to a conventional VCSEL, a lot of heat is generated from the elements due to the resonance characteristics, and therefore, low current is injected as the elements are damaged frequently according to the application of high current. This means that the effect of current diffusion of the current injected from the electrode cannot be expected much. Accordingly, there is a problem in that the efficiency is lowered as the current emitted from the upper electrode, which is positioned along the edge of the upper DBR, cannot uniformly pass through the current window at the center portion.

Korean Patent Publication No. 10-2018-0015630 (WO 2016/198282) discloses an oxidized VCSEL having a peak wavelength of 850 nm and a method of diversely forming a plurality of oxide layers in the upper DBR to improve the VCSEL. The manufacturing process thereof primarily invites non-uniformity in the reflectivity of the upper DBR and also generates a complicated problem in the process such as oxidation reprocess or the like for creating several current windows.

Meanwhile, although there is provided a method of forming a transparent ITO layer on the entire upper DBR and uniformly supplying the current emitted from an electrode of a ring shape to the center portion through the ITO, as a method of uniformly passing the current emitted from the upper electrode through the current window at the center portion, in this case, an expensive transparent electrode is required, and it is difficult to avoid abrupt degradation of throughput in the process of forming the ITO.

### SUMMARY OF THE INVENTION

Therefore, the present invention has been made in view of the above problems, and it is an object of the present invention to provide a high-efficiency oxidized VCSEL, which can induce stable flow and diffusion of electricity from an upper electrode of the VCSEL to a light emitting region.

Another object of the present invention is to provide a method of manufacturing a high-efficiency oxidized VCSEL, which can induce stable flow and diffusion of electricity from an upper electrode of the VCSEL to a light emitting region.

[symbol]

Terminologies

In the present invention, the term ‘high doping region’ means a region in which doping concentration is increased in a current diffusion layer by the doping accomplished after growth of the current diffusion layer.

In the present invention, the term ‘region in which doping concentration is increased’ includes a region in which the doping concentration is increased by diffusion after doping, as well as a region in which the doping concentration is increased by doping.

In the present invention, the term ‘center portion’ means an upper area of a current window of an oxidized VCSEL.

In the present invention, the term ‘periphery’ means a peripheral region other than the center portion.

To solve the problems as described above, the present invention provides an oxidized vertical cavity surface emitting laser (VCSEL) including a current diffusion layer having a high doping region at least in a portion between an upper electrode and a lower distributed Bragg reflector.

In the present invention, the current diffusion layer is a conductive layer having a relative high band gap, which performs a function of diffusing current flow so that the current emitted from the upper electrode may be diffused and supplied to an active layer via the lower distributed Bragg reflector.

In the present invention, the current diffusion layer is an epitaxially grown layer in a method such as a MOCVD to have a predetermined thickness and may have high conductivity, preferably two or more times, further preferably three or more times, further more preferably four or more times, and most preferably five or more times higher than the conductivity of the active layer, the upper and lower DBRs, and/or the substrate to prevent increase of operation voltage of the VCSEL.

In the present invention, the current diffusion layer may be a layer grown while being doped with a material such as Al, C or Mg to have conductivity and may use, for example, a material such as AlGaAs or GaP. The doping concentration of the current diffusion layer may be uniform at the same growth height and may vary according to height. Preferably, the doping concentration may be higher in a portion close to the upper electrode, i.e., on the top surface.

In an embodiment of the present invention, the current diffusion layer may be formed in a proper thickness considering the current supplied to the VCSEL and the intensity and wavelength of emitted laser, and the thickness may be preferably 2 μm or larger, further preferably 3 μm or larger, and further more preferably 4 μm or larger.

In the present invention, the grown current diffusion layer may have a doping concentration of 6.0×10¹⁸ atoms/cm³ to 8.5×10¹⁸ atoms/cm³.

In the present invention, the doping concentration of the high doping region may be increased as much as 0.5×10¹⁸ atoms/cm³ or higher, for example, 1.0×10¹⁸ atoms/cm³ or higher, 1.5×10¹⁸ atoms/cm³ or higher, 2.0×10¹⁸ atoms/cm³ or higher, and 2.5×10¹⁸ atoms/cm³ or higher by the doping accomplished after growth of the current diffusion layer.

In the present invention, the doping accomplished after growth of the current diffusion layer may be surface doping in which injection of dopant is accomplished from the surface, preferably surface doping in which metal atoms are injected from the surface as dopant.

In the present invention, the metal atom may be an alkali metal, an alkaline earth metal or a transition metal, and for example, it may be one or more selected among an alkali metal such as Li, Na, K, Rb or Cs, an alkaline earth metal such as Be, Mg, Ca, Sr or Ba, or a transition metal such as Sc, Ti, V, Cr, Mn, Fe, Co, Ni, Cu, Zn, Y, Zr, Nb, Mo, Tc, Ru, Rh, Pd, Ag, Cd, Pt, or Au, and may be Zn in an embodiment.

In the present invention, the high doping region may be formed in a portion of the current diffusion layer, preferably, at the center portion. The high doping region is preferably formed at the center portion and as far as a portion of the periphery contacting with the center portion, to be partially overlapped with a portion immediately under a ring-shaped upper electrode.

In the present invention, the high doping region is preferably formed on the surface and as much as a predetermined depth smaller than the thickness of the current diffusion layer, to facilitate diffusion of current in the horizontal direction, rather than in the vertical direction.

In the present invention, concentration of the high doping region may vary according to depth, and preferably, the high doping region may have a concentration profile of a form in which concentration increases according to depth and gradually decreases after reaching a maximum value.

In a preferred embodiment of the present invention, the high doping region may have a concentration profile in which the maximum concentration exists at a depth of 1 μm or lower, further preferably, 0.5 μm or lower, to facilitate diffusion in the horizontal direction.

Although it is not theoretically limited, light emitting efficiency of the oxided VCSEL is improved as the current flowing out from the bottom of the ring-shaped upper electrode positioning on the top of the current diffusion layer is rapidly diffused toward the center portion of the current diffusion layer through the high doping region formed on the surface of the center portion of the current diffusion layer and is smoothly supplied to the current window of the VCSEL positioning on the bottom of the center portion of the current diffusion layer.

In the present invention, the oxided vertical cavity surface emitting laser (VCSEL) may emit laser light having a peak wavelength of 860±10 nm (hereinafter, referred to as ‘860 nm peak wavelength’), and it is understood that the laser means a wavelength having a FWHM less than 5 nm.

In an embodiment of the present invention, the oxided vertical cavity surface emitting laser (VCSEL) may configure a light emitting column by stacking a lower electrode, a substrate, a lower distributed Bragg reflector, an active layer, a current window for emitting resonance laser light, an oxide layer formed to surround the periphery of the current window, an upper distributed Bragg reflector formed on the top surface of the current window and the oxide layer, a current diffusion layer having a high doping region in a portion of the upper surface, and upper electrodes. The light emitting column may be a circular or polygonal shape.

In the present invention, the substrate may be a substrate capable of MOCVD growth, preferably an n-GaAs substrate.

In the present invention, the active layer of the VCSEL is a layer for emitting light converted into laser light, and in an embodiment of the present invention, the active layer may include a GaAs quantum well and an AlGaAs quantum barrier layer.

In the present invention, the upper distributed Bragg reflector and the lower distributed Bragg reflector are used to reflect up and down the light emitted from the active layer to resonate the light.

In the present invention, the upper and lower DBRs may be DBRs repeatedly stacking a pair of reflection layers configured of a high refraction layer and a low refraction layer to reflect the light emitted from the active layer and the light reflected by an. opposite reflector.

In an embodiment of the present invention, the lower DBR may include 30 pairs, preferably 40 pairs of n-DBRs to completely, in practice, reflect the light reflected by the active layer and the upper DBR, and the upper DBR may have n-DBR pairs 5 to 10 pairs smaller than those of the lower DBR, and preferably, the upper DBR may be configured of 20 to 25 pairs of p-DBRs to enhance possibility of emitting light.

In an embodiment of the present invention, the upper distributed Bragg reflector and the lower distributed Bragg reflector may be a distributed Bragg reflector (DBR) having a structure alternately and repeatedly stacking an AlₓGa₁₋ₓAs layer of a high refractive index (0.8<x<1) and an Al_{y}Ga_{1-y}As layer of a low refractive index (<y<0.2).

In the present invention, the oxide layer is configured of an oxidizing material and may mean a layer in which an oxidized region and a non-oxidized region coexists for resonance. The oxide layer may be Al_{z}Ga_{1-z}As (0.95<z≤1) to be easily oxidized by high temperature steam. The oxide layer may be configured of an oxide layer of a ring shape and a current window of an inner center circle shape as the oxide layer is oxidized from the outer side to the center portion.

In the present invention, the diameter of the center circle configuring the current window in the oxide layer should be narrow as much as to be able to emit laser light, and preferably, the diameter may be less than 10 μm.

In the present invention, the oxide layer may be positioning on the top of the active layer, preferably inside the p-DBR not to give effect to the active layer, further preferably between the layers configuring the p-DBR. Further preferably, the oxide layer may be positioned below the upper p-DBR, for example, between a first pair and a second pair in the upper DBR, and may be applied at a thickness of 30 to 10 nm.

In an embodiment of the present invention, the oxidized VCSEL may achieve high efficiency at a low current, e.g., 30 mA or less, owing to the current diffusion layer formed on the surface and the doping unit formed at the center portion of the top surface of the current diffusion layer and may operate preferably in a range of 5 to 20 mA, most preferably at 10 mA. When the current exceeds 40 mA, laser light having a peak wavelength of 860 nm may not be generated due to the effect of heat generation.

In the present invention, the upper electrode may be formed in a ring shape so as not to shield emitted light, and preferably, the upper electrode may be a multi-layer electrode configured of Au, Pt and Ti. In an embodiment, thickness of the electrode may be around 2 micrometers.

In the present invention, the oxidized VCSEL may further include a reflection prevention layer to prevent reflection of emitted light. The reflection prevention layer may be positioned between the current diffusion layer and the upper electrode while covering the current diffusion layer. In addition, the reflection prevention layer may be positioning on the top of the oxidized VCSEL while covering the top of the upper electrode and the reflection prevention layer.

In an embodiment of the present invention, the reflection prevention layer may be configured of Si₃N₄ or SiO₂ and may be grown and applied at a thickness of about 100 to 500 nm, preferably 150 to 400 nm, and most preferably 200 to 300.

In an aspect, the present invention provides a manufacturing method of an oxidized vertical cavity surface emitting laser (VCSEL) including the steps of: epitaxially growing a current diffusion layer between an upper electrode and a lower distributed Bragg reflector; and forming a high doping region by injecting dopant into at least a portion of the current diffusion layer after growth of the current diffusion layer.

In the present invention, the high doping region is formed by stacking a dopant supply layer in at least a portion of the top surface of the current diffusion layer, forming the high doping region in at least a portion of the current diffusion layer by heating the dopant supply layer, and removing the dopant supply layer.

In an embodiment of the present invention, the surface doping may be accomplished through supply of dopant from the dopant supply layer stacked on the top surface of the current diffusion layer, for example, through diffusion of dopant, e.g., diffusion through heating. The dopant supply layer may be removed before the upper electrode is formed.

In an embodiment of the present invention, the dopant supply layer may be a ZnO or AZO layer, and the heating temperature may be adjusted according to non-crystallization of the current diffusion layer within a range of preventing generation of a defect according thereto.

In an embodiment of the present invention, the heating temperature may be less than 500° C., preferably 400 to 450° C., when Zn is doped on GaP from AZO, or may be less than 700° C., preferably 500 to 600° C., when Zn is doped on AlGaAs from ZnO.

In an embodiment of the present invention, the high doping region may have a doping concentration of 9.0×10¹⁸ atoms/cm³ to 1.2×10¹⁹ atoms/cm³, by adding a doping concentration increased by the doping accomplished after the growth to the doping concentration of the current diffusion layer.

In the present invention, the oxidized VCSEL may be manufactured using a general VCSEL manufacturing method, except forming a current diffusion layer and forming a high doping layer on the current diffusion layer.

In an embodiment of the present invention, the oxidized VCSEL may be manufactured in a method including the steps of: providing a substrate; forming a lower DBR on the top of the substrate; forming an active layer on the top of the lower DBR; forming a first upper DBR on the top of the active layer; forming an oxide layer on the top of the first upper DBR; forming a second upper DBR on the top of the oxide layer; forming a circular trench; oxidizing a periphery, except the center portion of the oxide layer; forming a current diffusion layer on the top of the second upper DBR; forming a high doping region in a portion of the current diffusion layer; forming a lower electrode on the bottom of the substrate; and forming a ring-shaped electrode on the top of the current diffusion layer.

### BRIEF DESCRIPTION OF THE DRAWINGS

FIG. 1 is a view showing an exploded cross-section of a conventional oxidized VCSEL.

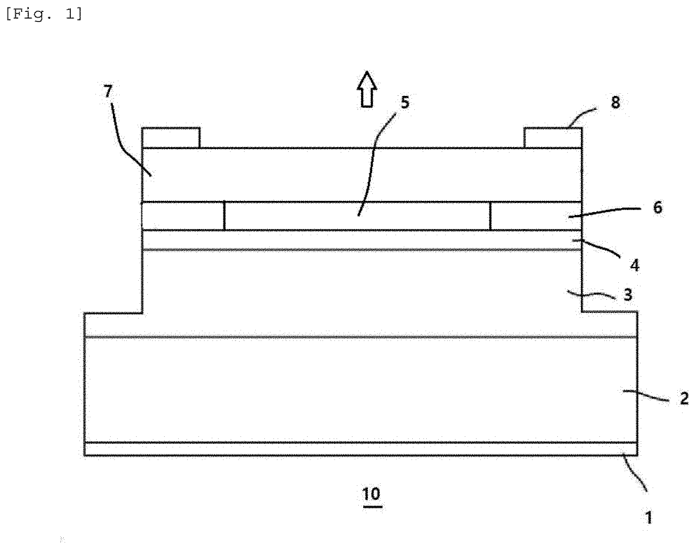

FIG. 2(a) is a view showing an SEM image of a DBR damaged when oxidization is progressed, and FIG. 2(b) is a view showing a shape of a current window, in which the black band shape is a trench (dented) area, and the center area is a column area for emitting light, of which the brighter area is an oxidized area.

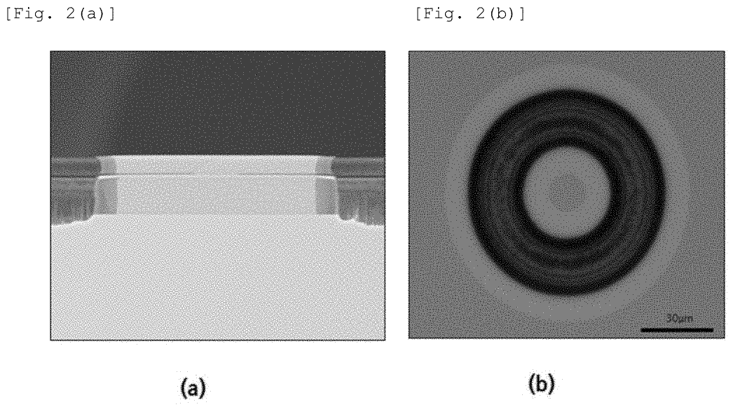

FIG. 3 is an isolated cross-sectional view showing the layer structure of an oxidized VCSEL according to an embodiment of the present invention.

FIG. 4 is a view showing the steps of forming a doping unit of a light diffusion layer in an oxidized VCSEL according to an embodiment of the present invention. (a) Dopant supply layer deposition step, (b) Heat doping step, (c) Dopant supply layer removing step, (d) Upper electrode forming step

FIG. 5 is a view showing an SEM picture photographing the cross-sectional area of a current diffusion layer having a doping unit of an oxidized VCSEL of the present invention.

FIG. 6 is a graph showing hole concentration and resistance of a current diffusion layer doped with Zn through heat treatment of 500° C., 600° C. and 700° C. and a non-doped current diffusion layer according to embodiment 1 of the present invention.

FIG. 7 is a graph showing doping concentration according to depth of a current diffusion layer doped with Zn through heat treatment of 500° C., 600° C. and 700° C. and depth of a non-doped current diffusion layer according to embodiment 1 of the present invention. The inserted figures are results of AFM.

FIG. 8 is a graph showing output power as a function of current (I) of a VCSEL chip having a current diffusion layer doped with Zn through heat treatment of 500° C., 600° C. and 700° C. and a non-doped current diffusion layer according to embodiment 1 of the present invention.

FIG. 9 is a graph showing the shapes of beam emission of a VCSEL chip having a current diffusion layer doped with Zn through heat treatment of 600° C. and a non-doped current diffusion layer according to embodiment 1 of the present invention.

FIG. 10 is a graph showing doping concentration according to depth of a current diffusion layer doped with Zn through heat treatment of 400° C., 450° C. and 500° C. and depth of a non-doped current diffusion layer according to embodiment 2 of the present invention. The inserted figures are results of AFM.

FIG. 11 is a graph showing output power of function current (I) of a VCSEL chip having a current diffusion layer doped with Zn through heat treatment of 400° C., 450° C. and 500° C. and a non-doped current diffusion layer according to embodiment 2 of the present invention.

FIG. 12 is a graph showing the shapes of beam emission of a VCSEL chip having a current diffusion layer doped with Zn through heat treatment of 450° C. and a non--doped current diffusion layer according to embodiment 2 of the present invention.

FIG. 13 is a view showing the cross-sectional structure of the VCSEL of embodiment 2 of the present invention.

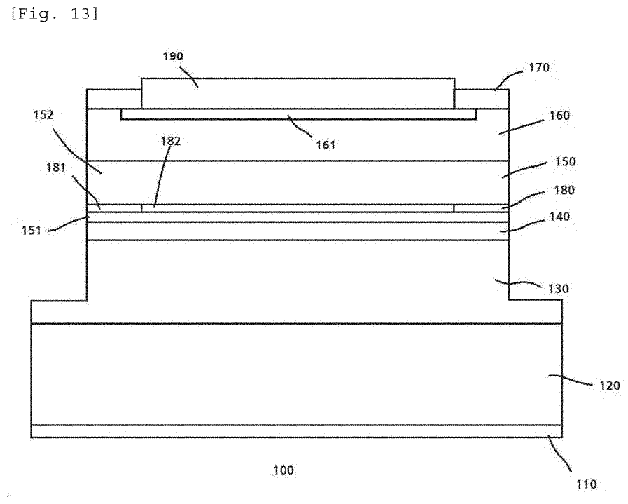

FIG. 14 is a view showing the process of manufacturing the VCSEL of embodiment 2 of the present invention.

### DESCRIPTION OF SYMBOLS

100: Oxidized VCSEL
110: Lower electrode
120: Substrate
130: Lower DBR
140: Active layer
150: Upper DBR
160: Current diffusion layer
161: High doping region
170: Upper electrode
180: Oxide layer
190: Reflection. prevention layer

### DETAILED DESCRIPTION OF THE PREFERRED EMBODIMENT

Hereinafter, the present invention will be described in detail through the embodiments. The embodiments described below are not to limit the present invention, but to illustrate the present invention.

### Embodiments 1

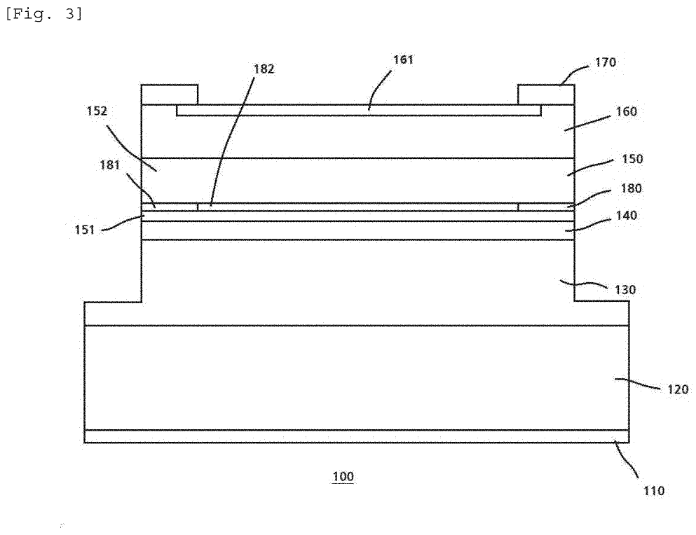

FIG. 3 shows the structure of a VCSEL layer which emits laser light having a peak wavelength of 860 nm and is applied with a p-AlGaAs current diffusion layer, of which the center portion of the top surface is doped with Zn, manufactured by a MOCVD system.

As shown in FIG. 3, an oxidized VCSEL 100 having a peak wavelength of 860 nm according of the present invention is an oxidized VCSEL 100 which emits laser light at toward the top of a substrate 120. The VCSEL 100 is grown on an n-type GaAs substrate 120 in a MOCVD method, uses trimethylgallium (TMGa) and trimethylammonium (TMAl) as group 3 sources, arsine (AsH₃) and phosphine (PH₃) as group 5 sources, and disilane (Si₂H₆) gas and cyclopentadienylmagnesium (Cp₂Mg) as n-doping and p-doping sources. Hydrogen H₂ is used as a carrier gas of all sources.

A lower electrode 110 is provided on the bottom surface of the substrate 120, and a lower n-DBR 130, in which an AlGaAs layer of high refractive index and an AlGaAs layer of low refractive index are repeatedly stacked in pairs, is provided on the top of the substrate 120. An Al_{0.85}Ga0_{0.15}As layer and an Al_{0.15}Ga_{0.85}As layer are repeatedly stacked 40 times.

An active layer 140 is provided on the lower DBR 130. The active layer 140 is configured of upper and lower confinement layers and a quantum well structure which emits a center wavelength of 860 nm. AlₓGa₁₋ₓAs (n-Al_{0.1}GaAs:Si and p-Al_{0.1}GaAs:Mg) is used as n- and p-confinement layers, and the quantum well structure is configured by repeatedly stacking a 5 nm GaAs quantum well and a 12 nm Al_{0.05}GaAs quantum barrier. The cavity length configured by the confinement layers and the quantum well is about 430 nm.

An upper p-DBR 150 including an oxide layer 180 is provided on the active layer 140. The oxide layer 180 is inserted between the layers of the pairs configuring the p-DBR 150 and may avoid direct contact with the active layer 140 to avoid damage of the active layer in the oxidization process. The oxide layer 180 is stacked on one or two pairs, among the 25 pairs, of the upper DBR, and the other pairs of the upper DBR are stacked on the oxide layer 180. Accordingly, the upper DBR 150 is configured of a first upper DBR 151 positioning on the bottom of the oxide layer 180 and a second upper DBR 152 positioning on the top of the oxide layer 180.

The upper p-DBR 150 includes an AlGaAs layer of high refractive index and an AlGaAs layer of low refractive index repeatedly stacked in pairs in the same way as the lower DBR and is configured of 25 pairs of Al_{0.85}Ga_{0.15}As layer and Al_{0.15}Ga_{0.85}As layer.

The oxide layer 180 includes a circular current window (oxidation aperture) 181 configured of Al_{0.98}Ga_{0.02}As having a thickness of about 50 nm at the center portion, and an oxide ring 182 of the periphery, which is formed by oxidizing the oxide layer using steam. The DBR reflectivity shows the excellent characteristic of a stop-band shape almost at 98%.

A GaP current diffusion layer 160 is grown to a thickness of 2 μm on the upper p-DBR 140 in a MOCVD method. A high doping region 161 is formed at the center portion of the top surface and in a portion of the periphery of the. AlGaAs current diffusion layer 160.

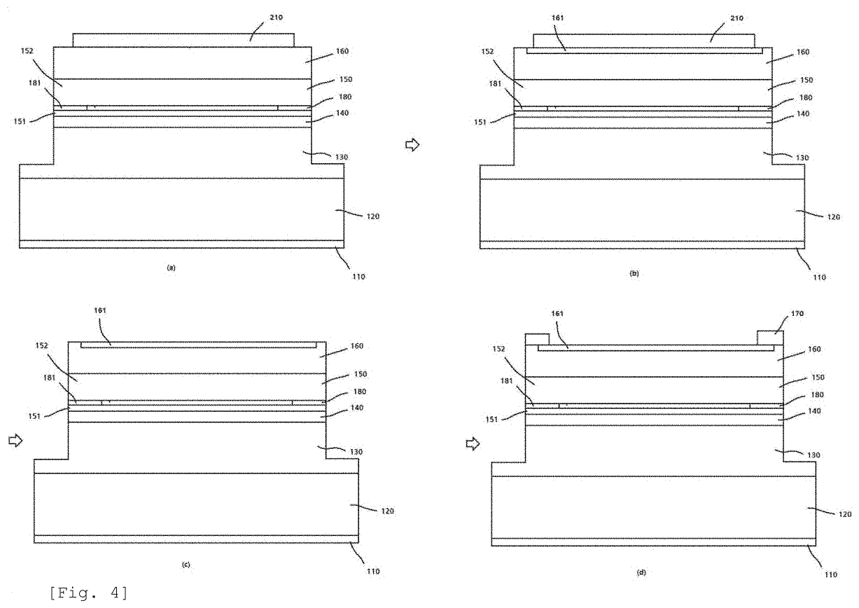

To form the high doping region 161, as shown in FIG. 4, (a) A pattern-controlled ZnO film 210 for supply of dopants and having a thickness of 5,500 nm (500 nm?) is stacked on the center portion of the top surface of the p-AlGaAs current diffusion layer 160. (b) The high doping region 161 is formed at the center portion of the top surface of the current diffusion layer 160 through heat treatment for 30 minutes at a temperature of 500° C., 600° C. and 700° C. (c) After the heat. treatment, the ZnO film is removed using HCl:DI solution. (d) After the ZnO film is removed, an upper electrode 170 of a ring shape is formed. The inner side of the upper electrode is formed to be partially overlapped with the high doping region 161.

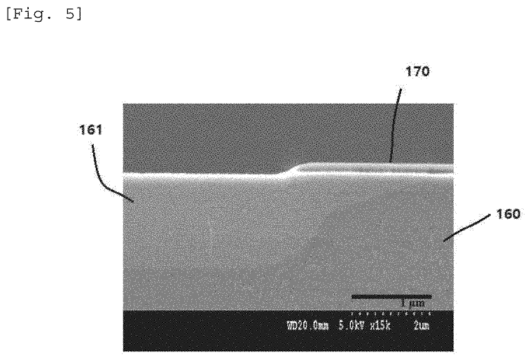

As a result of photographing the cross-sectional SEM, it is confirmed that the doping unit is formed as deep as about 1 μm from the top surface as shown in FIG. 5.

### Comparative Embodiment 1

Comparative embodiment 1 is embodied to be the same as the embodiment described above, except that there is no Zn doping.

### Test 1

Inspection has been performed on the products of the embodiment manufactured through heat treatment for Zn doping at a temperature of 500° C., 600° C. and 700° C. and on the product of the comparative embodiment (P++ AlGaAs) without having a Zn doping process.

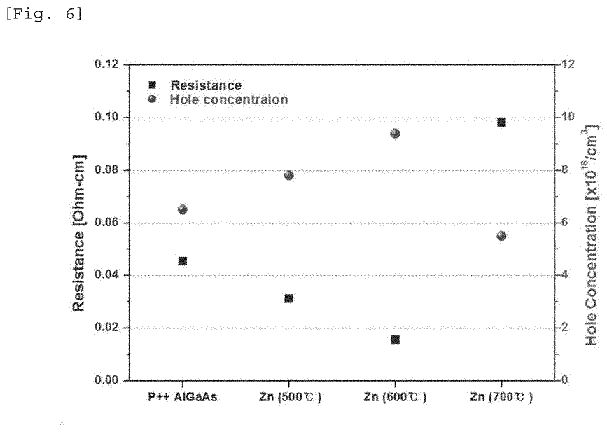

As shown in. FIG. 6, a resistance of 0.043 ohm-cm is shown in the comparative embodiment without having a Zn doping process, and this is considerably high compared with 0.033 and 0.012 ohm-cm of the products doped at 500° C. and 600° C. The product doped at 700° C. shows a high resistance of 0.98 ohm-cm. These results correspond to increase of the hole concentration, which is in a trade-off relation with the resistance, from 6.4×10¹⁸/cm³ of the comparative embodiment to 6.8×10¹⁸/cm³ and 9.3×10¹⁸/cm³ through heat treatment at 500° C. and 600° C., and abrupt decrease to 5.5×10¹⁸/cm³ at 700° C.

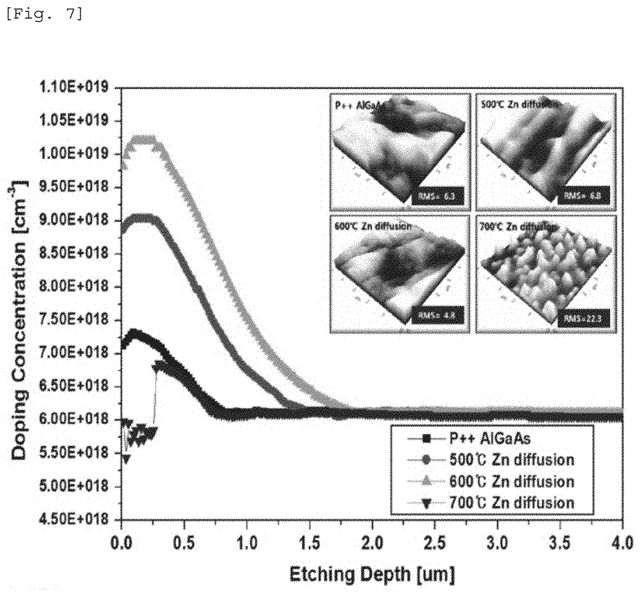

The doping curves of FIG. 7 show that the non-doping p++-AlGaAs current diffusion layer has concentration of 7.0×10¹⁸/cm³ only on the surface and has almost uniform concentration of 6.1×10¹⁸/cm³ at the other part. The maximum doping concentration of the P++ AlGaAs current diffusion layer is formed at a depth of 0.07 μm. Contrarily, the Zn-diffused AlGaAs current diffusion layer shows high doping concentration of 1.02×10¹⁹/cm³ and 9.0×10¹⁸/cm³ resulting from the heat treatment of 500° C. and 600° C., respectively. A product from the heat treatment of 700° C. shows a low doping concentration of 6.7×10¹⁸/cm³ and is analyzed as a defect caused by recrystallization or non-crystallization.

The inserted figures (AFM images) show that the surfaces of the non-doped product and the products obtained from 500° C. and 600° C. heat treatment are as smooth as to have a surface RMS value of 4.8 to 6.8, whereas the product of 700° C. heat treatment has an RMS value of 22.3, showing an uneven surface morphology. This implies many surface defects.

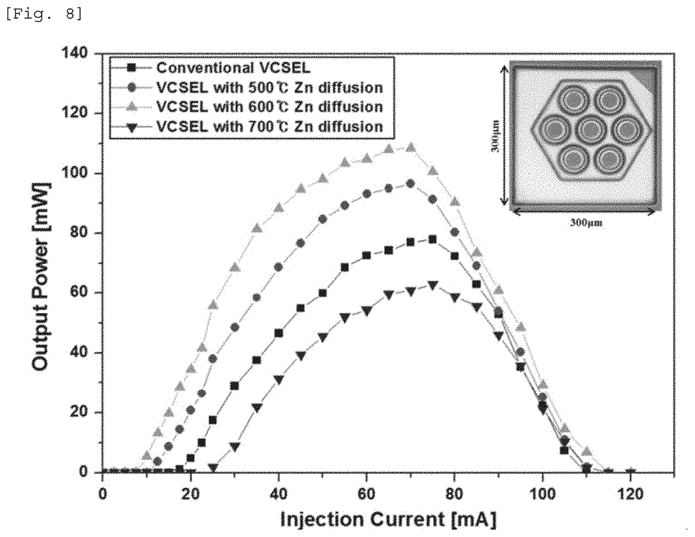

FIG. 8 is a graph showing output power as a function of current (I) of a manufactured VCSEL chip. When manufactured VCSEL chips are doped with Zn at 500° C. and 600° C., they show meaningfully high output power compared to that of a non-doped VCSEL chip. Output powers of 95 mW and 110 mW are generated from the products doped at 500° C. and 600° C., and this is an increase of 47% and 27% compared to 75 mW of the non-doped product.

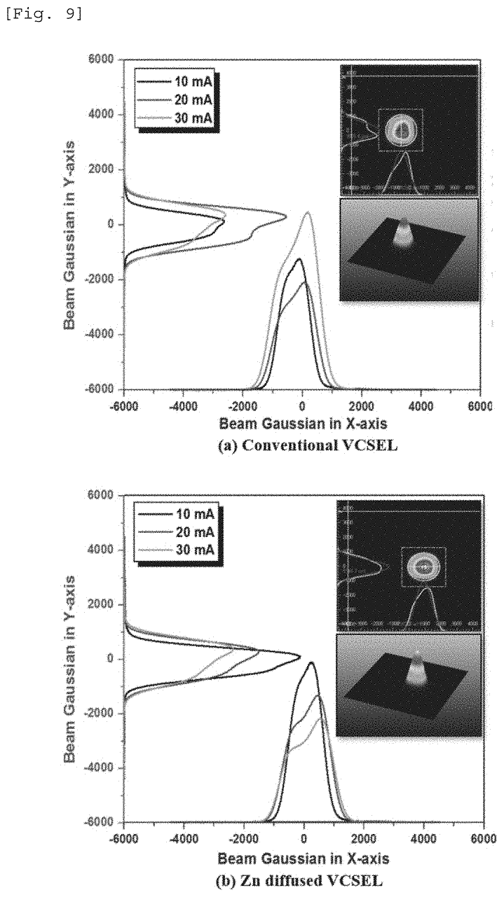

FIG. 9 shows far-field pattern lighting beam images of a Zn non-doped product of the comparative embodiment and a product of an embodiment doped with Zn at 600° C. The result is measured using a beam profiler system while maintaining the distance between a beam detector and a light pole to be 5 mm within a current injection range of 10 to 30 mA. The beam Gaussian curves of the chip of the comparative embodiment show different shapes and intensities on the x and y axes when the equal current is injected. The inserted figure of FIG. 9 shows the shapes of emitting an unbalanced 2D beam and a wide 3D beam. Contrarily, the beam Gaussian curves of the chip of the embodiment show the shape of a meaningfully balanced 2D beam on the x and y axes when the equal current is injected and show the shape of a sharp 3D beam.

### Embodiment 2

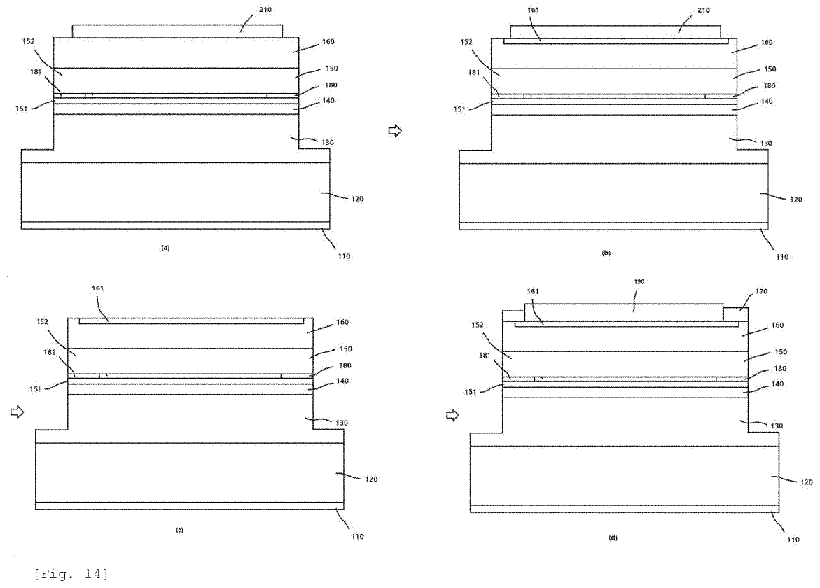

As shown in FIG. 14, the layer structure of an oxidized VCSEL 100 having a peak wavelength of 860 nm according of the present invention is the same as FIG. 3 of embodiment 1, except that a GaP layer is used as the current diffusion layer 160 and a SiN reflection prevention layer 190 is additionally formed at the inner area of the upper electrode 170.

The high doping region 161 is formed as shown in FIG. 5. (a) An aluminum zinc oxide (AZO) film 210 for supply of dopants and having a thickness of 500 nm is stacked on the center portion of the top surface of the GaP current diffusion layer 160. (b) The high doping region 161 is formed at the center of the top surface of the current diffusion layer 160 through heat treatment for 2 hours at a temperature of 400° C., 450° C. and 500° C. in a furnace of a nitrogen atmosphere. (c) After the heat treatment, the AZO film is removed using HCl:DI solution. (d) After the AZO film is removed, an upper electrode 170 of a ring shape is formed. The inner side of the upper electrode is formed to be partially overlapped with the high doping region 161. The SiN reflection prevention layer 190 is formed in the inner area of the upper electrode 170.

### Comparative Embodiment 2

Comparative embodiment 2 is embodied to be the same as the embodiment described above, except that there is no Zn doping.

### Test 2

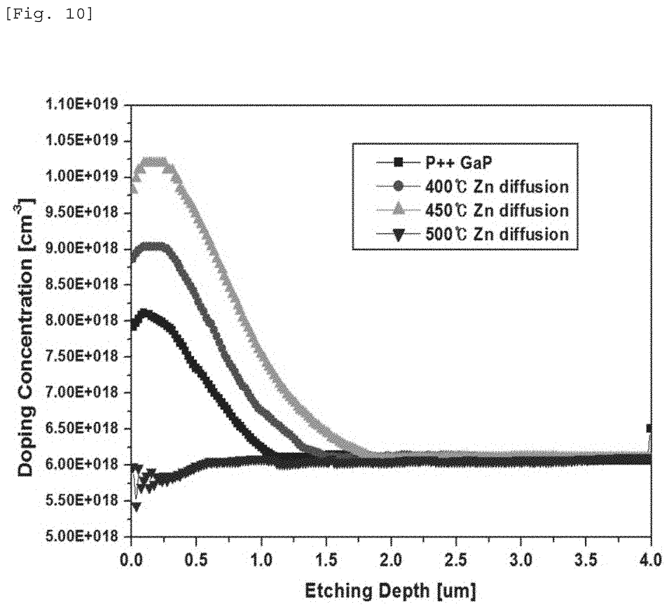

Inspection has been performed on the products of embodiment 2 manufactured through heat treatment for Zn doping at a temperature of 400° C., 450° C. and 500° C. and on the product of comparative embodiment 2 (P++ AlGaAs) without having a Zn doping process. A doping concentration profile of the Zn diffused GaP area after the heat treatment process is shown in FIG. 10. It is sample etched current voltage (ECV) data according to the heat treatment conditions of 400° C., 450° C. and 500° C. acted as an important variable when the Zn diffusion is progressed. The ECV measurement confirms doping concentration by etching as deep as about 4 μm into the sample from the surface thereof, and in the case of a general sample to which the Zn diffusion process is not applied, it is confirmed that the maximum doping concentration has a value of about 8.2×10¹⁸ per cm³. When the Zn diffusion is progressed, large values of about 9.1×10¹⁸ and 1.2×10¹⁹ of considerably increased doping concentration are confirmed under the heat treatment condition of 400° C. and 450° C. However, a phenomenon of greatly decreasing the doping concentration is conformed under the heat treatment condition of about 500° C. It is determined that this phenomenon is caused by non-crystallization of GaP according to high temperature and occurrence of defects according thereto.

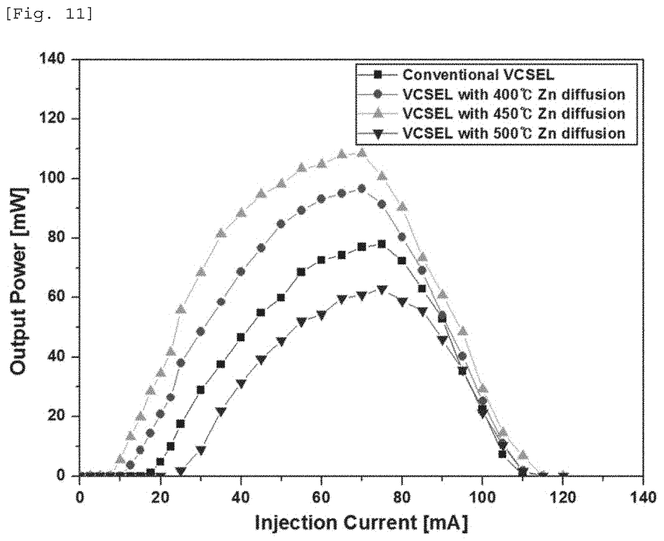

FIG. 11 is a graph showing output power as a function of current (I) of a manufactured VCSEL chip. It shows optical efficiency of a non-doped VCSEL according to application of current (comparative embodiment 2) and a VCSEL that is highly doped through Zn diffusion. In the case of the comparative embodiment, the VCSEL has optical efficiency of about 78 mW. Contrarily, embodiment 2 shows that the efficiency is greatly increased when a Zn diffused doping unit is applied. When Zn diffusion of 400° C. and 450° C. is applied, the maximum optical efficiency shows high efficiency of 96 mW (24% increase) and 110 mW (42% increase). However, when Zn diffusion of about 500° C. is applied, the optical efficiency abruptly decreases and shows a small value of about 60 mW (22% decrease). Such a result of the optical efficiency corresponds to the result and tendency of the ECV of FIG. 10.

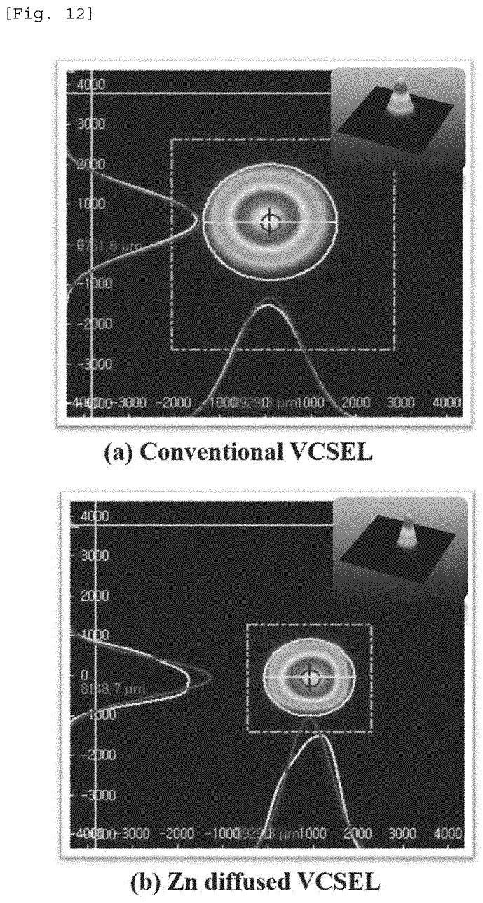

FIG. 12 shows two-dimensional and three-dimensional images of a lighting beam of a general VCSEL (conventional VCSEL) of comparative embodiment 2 and a lighting beam of a VCSEL Zn-diffused at 450° C., measured by a beam profiler. Intensity of light on the x axis and y axis is measured at a distance of about 5 mm at about 30 mA. In the case of the two-dimensional image, it is confirmed that the Zn diffused VCSEL has a beam shape smaller than that of the conventional VCSEL, and when this is confirmed three-dimensionally, it is confirmed that the lighting beam has a more clearly concentrated light shape. It is confirmed that the lighting beam of the VCSEL is concentrated further more by the high doping region of the surface diffused by Zn.

According to the present invention, there is provided a new current diffusion layer which can protect the upper DBR in the oxidizing process, improve flow of current, and facilitate diffusion of current from a peripheral electrode to the current window of the center portion.

Although the present invention has been illustrated and described in detail in the drawings and above descriptions, it is regarded that the illustrations and descriptions are illustrative or exemplary and not restrictive. Other changes will be clear to those skilled in the art from the present invention. These changes may be accompanied with other features that can be used instead of or in addition to the features known in this field and described in this specification. Modifications of the disclosed embodiments may be understood and affected by those skilled in the art from the learning of the drawings, the present invention and the attached claims. In the claims, the term “include” does not exclude other elements or steps, and description of an indefinite article does not exclude a plurality of elements or steps. The fact that specific measures are cited in dependent claims different from each other does not indicate that combinations of these measures cannot be used advantageously. In the claims, arbitrary reference symbols should not be interpreted as limiting the scope thereof.

What is claimed is:

1. An oxidized vertical surface emission laser (VCSEL) comprising a current diffusion layer having a high doping region at least in a portion between an upper electrode and a lower distributed Bragg reflector.

2. The oxidized VCSEL according to claim 1, wherein the current diffusion layer is an epitaxially grown transparent conductive layer.

3. The oxidized VCSEL according to claim 1, wherein the current diffusion layer is configured of AlGaAs or GaP.

4. The oxidized VCSEL according to claim 2, wherein the epitaxially grown current diffusion layer has a doping concentration of 6.0×10¹⁸ atoms/cm³ to 8.5×10¹⁸ atoms/cm³.

5. The oxidized VCSEL according to claim 1, wherein doping concentration of the high doping region increases as much as 1.0×10¹⁹ atom/cm³ or higher by doping accomplished after growth of the current diffusion layer.

6. The oxidized VCSEL according to claim 5, wherein the doping is surface doping.

7. The oxidized VCSEL according to claim 1, wherein the high doping region is doped with any one or more selected from a group including Li, Na, K, Rb, Cs, Be, Mg, Ca, Sr, Ba, Sc, Ti, V, Cr, Mn, Fe, Co, Ni, Cu, Zn, Y, Zr, Nb, Mo, Tc, Ru, Rh, Pd, Ag, Cd, Pt, and Au.

8. The oxidized VCSEL according to claim 1, wherein the high doping region is formed at a center portion of the current diffusion layer.

9. The oxidized VCSEL according to claim 1, wherein the high doping region is formed at a center portion of the current diffusion layer and a portion of a periphery contacting with the center portion.

10. The oxidized VCSEL according to claim 8, wherein the high doping region is formed on a surface and as much as a predetermined depth smaller than a thickness of the current diffusion layer.

11. The oxidized VCSEL according to claim 1, wherein the high doping region has a concentration profile in which the concentration increases according to depth to reach a maximum value and gradually decreases thereafter.

12. The oxidized VCSEL according to claim 11, wherein a maximum concentration of the concentration profile is located at position 0.5 μm or lower from a top surface.

13. The oxidized VCSEL according to claim 1, further comprising a lower electrode, a substrate, a lower DBR, an active layer, an oxide layer having a current window at a center portion, and an upper DBR.

14. The oxidized VCSEL according to claim 13, wherein the oxide layer is positioned between layers of the upper DBR.

15. The oxidized VCSEL according to claim 1, wherein the high doping region is doped with Zn.

16. A manufacturing method of an oxidized vertical surface emission laser (VCSEL), the method comprising the steps of:
epitaxially growing a current diffusion layer between an upper electrode and a lower distributed Bragg reflector; and
forming a high doping region by injecting dopant into at least a portion of the current diffusion layer after growth of the current diffusion layer.

17. The method according to claim 16, wherein the high doping region is formed by stacking a dopant supply layer in at least a portion of a top surface of the current diffusion layer, forming the high doping region in at least a portion of the current diffusion layer by heating the dopant supply layer, and removing the stacked dopant supply layer.

18. The method according to claim 17, wherein the high doping region doped with Zn is formed by stacking a ZnO dopant supply layer on the GaP current diffusion layer and heating at a temperature of 400 to 450° C.

19. The method according to claim 17, wherein the high doping region doped with Zn is formed by stacking an AZO dopant supply layer on the AlGaAs current diffusion layer and heating at a temperature of 500 to 600° C.
